(19) United States
(12) Patent Application Publication
(10) Pub. No.: US 2003/0071318 A1
(43) Pub. Date: Apr. 17, 2003

(54) Optical sub-assembly housing structure for an optical transceiver module

(76) Inventor: Szu-Chun Wang, Hsinchu City (TW)

Correspondence Address: BACON & THOMAS, PLLC, 625 SLATERS LANE, FOURTH FLOOR, ALEXANDRIA, VA, 22314

(21) Appl. No.: 09/973,913

(22) Filed: Oct. 11, 2001

(51) Int. Cl. H01L 31/0203

(52) U.S. Cl. 257/434

(57) ABSTRACT

An Optical Sub-Assembly housing structure for an optical transceiver module includes a plastic housing holding the light source unit on the inside, the housing having a tubular front coupling portion adapted to hold an optical fiber cable, the tubular front coupling portion having a tapered front opening for guiding the inserted optical fiber cable into position, and a longitudinal slot that makes the tubular front coupling portion deformable for high precision positioning and re-connection performance of the inserted optical fiber cable.

### BACKGROUND OF THE INVENTION

The present invention relates an Optical Sub-Assembly (OSA) housing structure, more particularly, to an optical fiber cable and laser diode/photodiode housing for an optical transceiver module which has high precision positioning and reconnection performance but is inexpensive to manufacture.

Following fast development of communication technology, a variety of wired as well as wireless communication network systems and components have been developed. Since wireless communication cannot completely eliminate interferences, wired communication is more intensively accepted. Wired communication uses a cable as a transmission medium to transmit electronic or optical signal. Optical signal transmission speed is very fast. The transmission medium for optical communication is optical fiber cable. And the optical signal emitting and receiving component is optical transceiver module. For a receptacle type optical transceiver module there builds two Optical Sub-Assembly (OSA) modules, transmitter OSA and receiver OSA, in it. The communication signals are converted to optical pulses and transmitted out to an optical fiber cable within a transmitter OSA. And the receiver OSA receives the optical pulses from fiber and converts them into electric signals. The transmitter and receiver OSA are generally comprised of a set of housing, and a light emitting or receiving element. The optical fiber cable, which can be a single-mode or multi-mode fiber ending with connector, having the ends respectively fastened to the housing of the transmitter module and the housing of the receiver module. The light-emitting element of the transmitter OSA can be a light emitting diode, or laser diode. The light-receiving element of the receiver OSA can be a photodiode or photodiode with trans-impedance-amplifier. FIG. 5 shows a transmitter OSA structure for an optical transceiver module according to the prior art. According to this structure, the light-emitting element A3 has a light source unit A31 and a plurality of contact pins A32 backwardly extended from the light source unit A31 for connection to respective contacts of a circuit board; the housing A is injection-molded from plastics, comprising a hollow housing base A1, which holds the light source unit A31 of the light-emitting element A3 on the inside, a tubular front coupling portion A2 forwardly extended from the hollow housing base A1, the tubular front coupling portion A2 having a longitudinal passage hole A22 and a front opening A21 with a tapered orifice A211, and a condensing lens A23 formed integral with the rear end of the passage hole A22 and adapted to condense light from the light source unit A31 of the transceiver element A3 onto the fiber optic cable being inserted into the passage hole A22. This structure is still not satisfactory in function. Because the housing A is injection-molded from plastics for the advantage of low manufacturing cost, the tubular front coupling portion A2 tends to be affected by ambient temperature to change the diameter of the passage hole A22. A significant change of the diameter of the passage hole A22 causes the inserted optical fiber cable to be deviated from the focal point. In case the tubular front coupling portion A2 contracts severely, the diameter of the passage hole A22 will be greatly reduced, thereby causing the worker unable to insert the optical fiber cable into the passage hole A22. FIG. 6 shows another prior art design. According to this structure, the housing base A1 and the tubular front coupling portion A2 of the housing A are two separated members made of stainless steel and fastened together by a laser welding technique. This structure eliminates the aforesaid problems, however it is expensive to manufacture. FIG. 7 shows still another transceiver element and housing structure according to the prior art. According to this design, the housing B comprises a housing base B1 holding a transceiver element (not shown), which transceiver element has contact pins extended out of the housing base B1 for connection to respective contacts of a circuit board, a front coupling portion B2 forwardly extended from the housing base B1, the front coupling portion B2 having a front opening B21, and a precision ceramic tube B4 mounted inside the front coupling portion B2. The ceramic tube B4 has a passage hole B41 extended through front and rear ends thereof, and a tapered guide face B411 in the front end of the passage hole B41. The use of the precision ceramic tube B4 greatly increases the manufacturing cost of the transceiver module. FIG. 8 shows a yet further transceiver element and housing structure according to the prior art. According to this structure, the housing B comprises a precision ceramic tube B4 mounted in the front coupling portion B2. The precision ceramic tube B4 has a longitudinal split B42 that makes the precision ceramic tube B4 radially compressible. Further, the front coupling portion B2 has a tapered guide face B211 in the front opening B21 thereof. The installation of the precision ceramic tube B4 facilitates quick and positive installation of a optical fiber cable in the front coupling portion B2 of the housing B. However, the use of the precision ceramic tube B4 greatly increases the manufacturing cost of the transceiver module.

### SUMMARY OF THE INVENTION

The present invention has been accomplished to provide An Optical Sub-Assembly housing structure for an optical transceiver module, which eliminates the aforesaid drawbacks. It is the main object of the present invention to provide An Optical Sub-Assembly housing structure, which is inexpensive to manufacture with high precision and re-connection performance, especially very suitable for single mode fiber cable use. To achieve this and other objects of the present invention, the Optical Sub-Assembly housing comprises a plastic housing and a transceiver element. The transceiver element can be a light emitting diode, a laser diode, a photodiode or a photodiode with trans-impedance-amplifier. The housing comprises a housing base defining a bottom open chamber that holds the light source unit of the transceiver element, and a tubular front coupling portion forwardly extended from the housing base and adapted to hold a optical fiber cable in alignment with the light source unit of the transceiver element. The tubular front coupling portion has a tapered front opening for guiding the inserted optical fiber cable into position, and a longitudinal slot that makes the tubular front coupling portion deformable for quick positioning of the inserted optical fiber cable.

### BRIEF DESCRIPTION OF THE DRAWINGS

FIG. 1 is an elevational view of the preferred embodiment of the present invention.

FIG. 2 is an exploded view of the preferred embodiment of the present invention.

FIG. 3 is a sectional view of the preferred embodiment of the present invention before the installation of the transceiver element in the bottom open chamber of the housing.

FIG. 4 is a sectional assembly view of the present invention.

FIG. 5 is a side view in section of a prior art design.

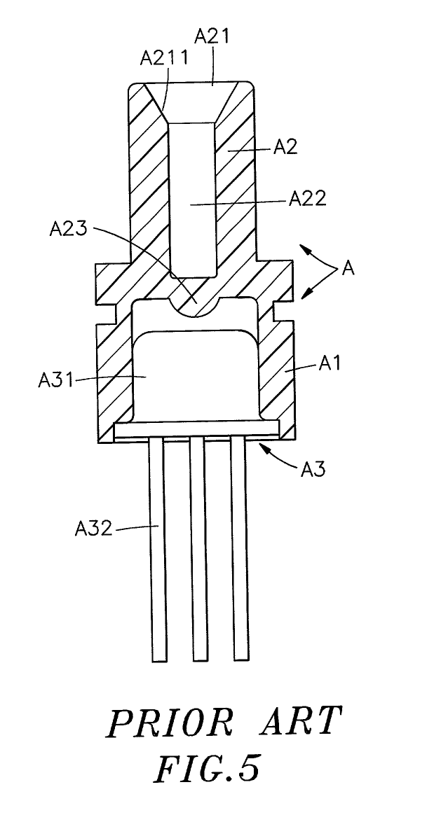

FIG. 6 is a side view in section of another prior art design.

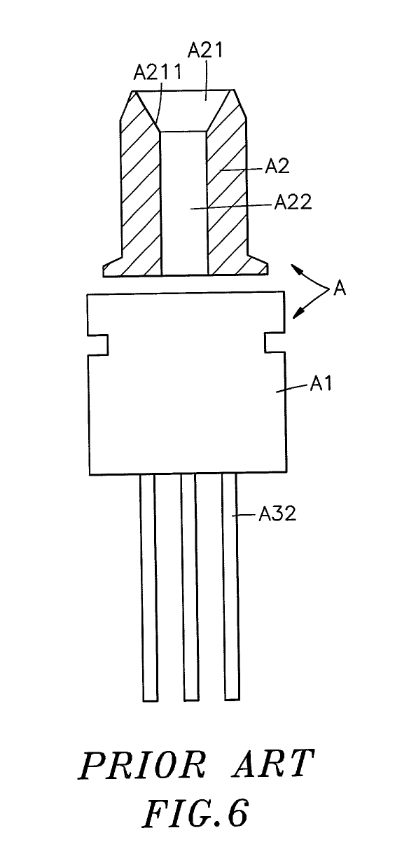

FIG. 7 is a side view in section of still another prior art design.

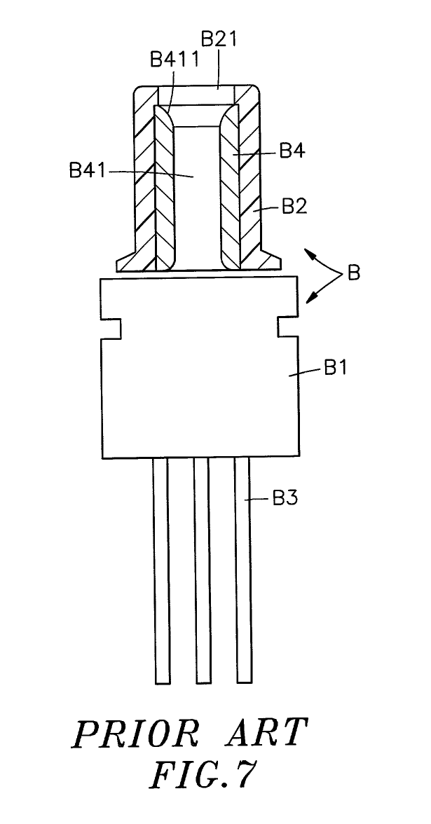

FIG. 8 is a side view in section of a yet further prior art design.

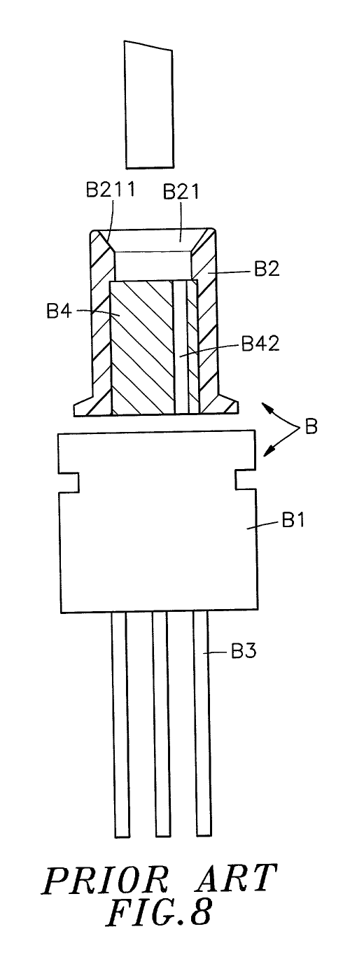

### DETAILED DESCRIPTION OF THE PREFERRED EMBODIMENT

Referring to FIGS. from 1 through 3, a transceiver element and housing structure in accordance with the present invention is shown comprised of a housing 1, and a transceiver element 2. The housing 1 is injection-molded from plastics, comprising a housing base 11, a bottom open chamber 111 defined in the housing base 11, an elongated front coupling portion 12 forwardly extended from the housing base 11, a front opening 121 in the remote end of the elongated front coupling portion 12, a passage hole 120 axially extended through the front coupling portion 12 in communication between the front opening 121 and the bottom open chamber 111, a neck 123 disposed between the passage hole 120 and the bottom open chamber 111, a tapered guide face 1211 in the front opening 121, and a longitudinal slot 122 cut through the peripheral wall of the elongated front coupling portion 12 and longitudinally upwardly extended from the connection area between the elongated front coupling portion 12 and the housing base 11 to the connection area between the front opening 121 and the passage hole 120. The diameter of the tapered guide face 1211 reduces gradually in direction from the front opening 121 toward the passage hole 120. The transceiver element 2 comprises a light source unit 21 received in the bottom open chamber 111 of the housing 1, a condensing lens 211 at the center of the front side of the light source unit 21, and a plurality of contact legs 22 backwardly extended from the light source unit 21 for connection to respective contacts in a circuit board (not shown).

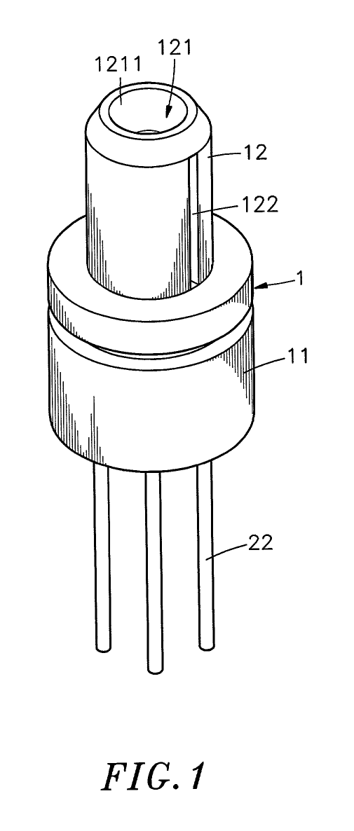

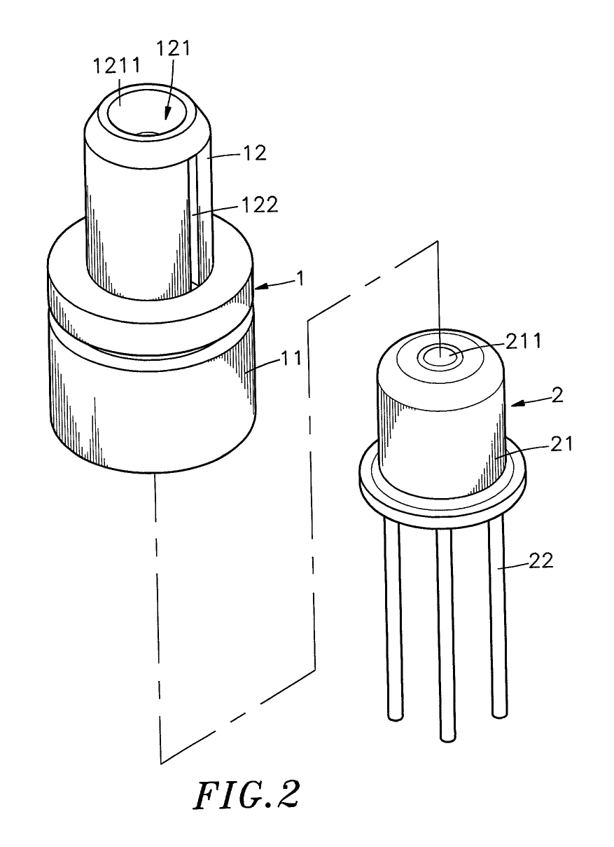

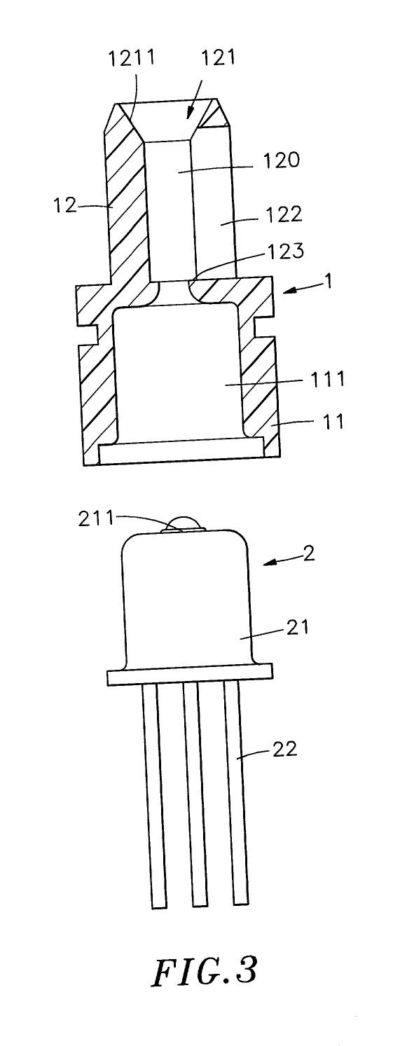

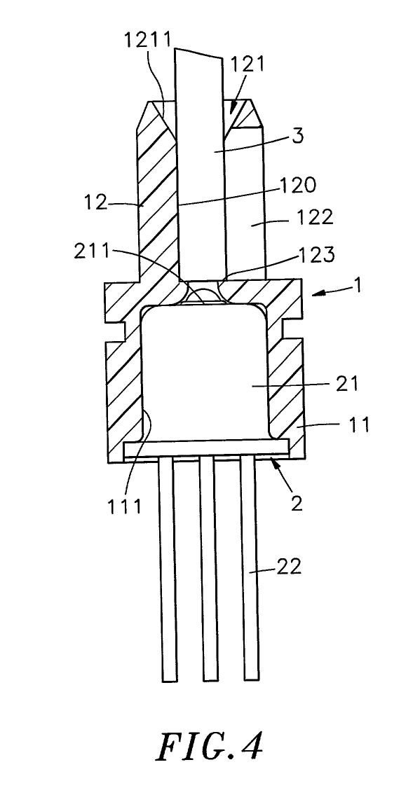

Referring to FIG. 4 and FIGS. 1 through 3 again, a single mode or multi-mode optical fiber cable 3 is inserted through the front opening 121 and guided by the tapered guide face 1211 into the passage hole 120. The optical fiber cable 3 has a diameter slightly greater than the inner diameter of the passage hole 120. Because the housing 1 is injection-molded from plastics and has a longitudinal slot 122 in the elongated front coupling portion 12, the elongated front coupling portion 12 is forced to deform when inserting the optical fiber cable 3 into the passage hole 120 with force. When inserted into position, the optical fiber cable 3 is stopped at the neck 123 of the housing 1 and aimed the condensing lens 211 of the transceiver element 2, and the friction force between the periphery of the optical fiber cable 3 and the inside wall of the elongated front coupling portion 12 secures the optical fiber cable 3 firmly to the elongated front coupling portion 12 of the housing 1. Because the housing 1 is injection-molded from plastics, its fabrication cost is low.

Further, two or more longitudinal slots 122 may be made in the elongated front coupling portion 12 of the housing 1. The transceiver element 2 can be a light emitting diode, a laser diode, or a photo diode.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A Optical Sub-Assembly housing structure: a plastic housing, said plastic housing comprising a housing base, a bottom open chamber defined in said housing base, an elongated front coupling portion forwardly extended from said housing base, a front opening in one end of said elongated front coupling portion remote from said housing base for the insertion of a optical fiber cable into the inside of said housing, and a passage hole axially extended through said front coupling portion in communication between said front opening and said bottom open chamber and adapted to hold a optical fiber cable; and a transceiver element, said transceiver element comprising a light source unit mounted in the bottom open chamber of said housing, and a plurality of contact legs backwardly extended from said light source unit for connection to respective contacts of a circuit board; wherein said plastic housing has at least one longitudinal slot cut through the periphery of said elongated front coupling portion, making said elongated front coupling portion radially compressible.

2. The Optical Sub-Assembly housing as claimed in claim 1 wherein said housing comprises a tapered guide face disposed in said front opening and adapted to guide a optical fiber cable into said passage hole, said tapered guide face having a diameter gradually reduced in direction from said front opening toward said passage hole.

3. The Optical Sub-Assembly housing as claimed in claim 1 wherein said at least one elongated slot of said housing respectively longitudinally extended from the connection area between said elongated front coupling portion and said housing base to the connection area between said front opening and said passage hole.

4. The Optical Sub-Assembly housing as claimed in claim 1 wherein said housing comprises an annular neck disposed between said bottom open chamber and said passage hole and adapted to stop the inserted optical fiber cable in said passage hole.

5. The Optical Sub-Assembly housing as claimed in claim 1 wherein said transceiver element is a light emitting diode.

6. The Optical Sub-Assembly housing as claimed in claim 1 wherein said transceiver element is a laser diode.

7. The Optical Sub-Assembly housing as claimed in claim 1 wherein said transceiver element is a photodiode.

8. The Optical Sub-Assembly housing as claimed in claim 1 wherein said transceiver element is a photodiode with trans-impedance-amplifier.
